(19) United States
(12) Patent Application Publication
(10) Pub. No.: US 2026/0317551 A1
(43) Pub. Date: Oct. 15, 2026

(54) AL-RICH ALCRN-BASED COATINGS FOR BROAD RANGE OF APPLICATIONS

(71) Applicant: OERLIKON SURFACE SOLUTIONS AG, PFÄFFIKON, PFÄFFIKON (CH)

(72) Inventors: Alexandre Jean François MICHAU, FELDKIRCH (AT); Denis KURAPOV, WALENSTADT (CH)

(21) Appl. No.: 19/485,844

(22) PCT Filed: May 23, 2024
(86) PCT No.: PCT/EP2024/064314

§ 371 Date: Nov. 19, 2025

Related U.S. Application Data
(60) Provisional application No. 63/503,781, filed on May 23, 2023.

(51) Int. Cl. C09D 1/00; C23C 14/06

(52) U.S. Cl. CPC C09D 1/00; C23C 14/0641

(57) ABSTRACT

An AlCrN-based coating includes an Al-rich AlCrN layer with formula AlₓCr₁₋ₓN, a non-Al-rich AlCrN layer with formula Al_{y}Cr_{1-y}N, and an Al-variable AlCrN layer with formula Al_{z}Cr_{1-z}N. The Al-variable AlCrN layer is a transition layer between the non-Al-rich AlCrN layer and the Al-rich AlCrN layer. Coefficients x, y and z correspond to atomic aluminum concentration in the respective layers when only aluminum and chromium are considered for calculation and are in a range of 0.76<x≤0.82, 0.60≤y≤0.76, and 0.60≤z≤0.82.

The present invention relates to Al-rich AlCrN-based coatings (hereafter also called Al-rich AlCrN coatings for simplifying nomenclature) exhibiting enhanced performance in particular for protection and improvement of performance of cutting tools and forming tools.

Furthermore, the present invention relates to a method for producing the inventive Al-rich AlCrN-based coatings.

Within the scope of the present invention the inventors studied a possible correlation between deposition conditions, properties and cutting performance of Al-rich AlCrN wear protective coatings produced by reactive arc evaporation.

This patent application claims the benefits of the U.S. provisional application Ser. No. 63/503,781, filed on May 23, 2023, the entire contents of which are hereby expressly incorporated by reference.

### PRIOR ART

AlCrN is a widely used coating material that has been used and studied:
For example, as a monolayer, introduced in 2004 as a sixth-generation coating by Balzers as BALINIT® ALCRONA, since upgraded in BALINIT® ALCRONA PRO in 2010.
As part of the product portfolio of almost every coating company in the tooling market.
As AlCrN system with properties tuned by alloying it with additional metal elements, metalloid elements, and further elements.
As AlCrN system produced by using different processes and for different applications.

Known coatings are for example AlCrN monolayer coatings having a ratio of Al-content in relation to Cr-content lower in atomic percentage lower than 70/30. Such coatings commonly exhibit a strong columnar morphology and are entirely deposited with one target material. This combination of features gives them a very good performance in several cutting and forming operations. Also other known coatings are synthetized by alloying the AlCrN system with additional elements such as Ti, Si, B, O, C, and others, that modify the characteristics and properties of AlCrN in order to achieve better performance in cutting or forming operations.

Known coatings are for example based on AlCrBN to achieve better performance in gear cutting applications or based on AlCrTiN to achieve also better performance in gear cutting applications. These good performances are usually resulting from a combination of properties and features from the coating.

In the case of the above-mentioned coatings based on AlCrBN or AlCrTiN, these coatings are known to be well-suited for good performance in only one application, and thereof for other applications other coatings are needed.

Some AlCrN coatings known coatings can somewhat be used as broad-band coatings, however several limits can be identified. As such coatings are composed of only pure AlCrN, it gives the coating a homogeneous morphology, a strongly marked columnar growth, which is not optimal to stay properly on a sharp cutting edge of a cutting tool. In addition, because the morphology is homogeneous, the only interfaces being the ones formed between the columns of the coating, cracks can propagate easily from the top surface to the interface with the substrate and cause serious damage to the coating such as chipping. Moreover, AlCrN is a good system with balanced properties, but still it can be improved, notably regarding its mechanical properties (indentation hardness and indentation modulus typically) and high temperature oxidation resistance. This “room for improvement” is crucial to reach better performance of tools in a big variety of more demanding cutting and forming operations.

Therefore, there is still a need of AlCrN-based coatings that meet the increasing demands of the customers for new applications for improvements of the properties of such coatings for meeting the increasing exigencies and are at the same time best suitable for several applications.

### OBJECTIVE OF THE PRESENT INVENTION

The main objective of the present invention is to alleviate the disadvantages of the prior art and to provide a coating that can be used as a broad-band coating, capable of performing well in a lot of different applications.

### DESCRIPTION OF THE PRESENT INVENTION

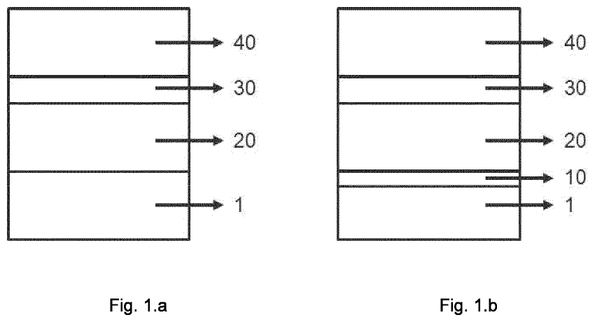

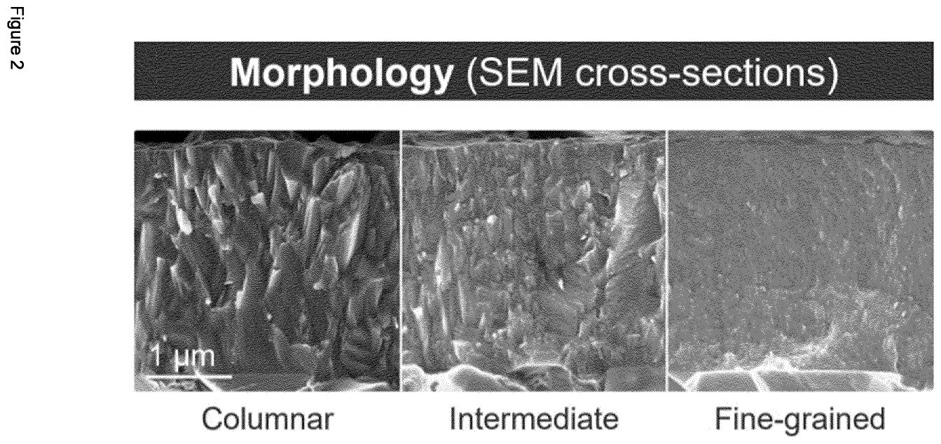

The main objective of the present invention is attained by providing an AlCrN-based coating comprising an Al-rich AlCrN layer having chemical element composition corresponding to the formula AlₓCr₁₋ₓN, with x being a coefficient corresponding to the concentration of aluminum in atomic concentration in the Al-rich AlCrN layer, when only aluminum and chromium are considered for the calculation, an non-Al-rich AlCrN layer having chemical element composition corresponding to the formula Al_{y}Cr_{1-y}N, with y being a coefficient corresponding to the concentration of aluminum in atomic concentration in the non-Al-rich AlCrN layer, when only aluminum and chromium are considered for the calculation, and an Al-variable AlCrN layer having chemical element composition corresponding to the formula Al_{z}Cr_{1-z}N, with z being a coefficient corresponding to the concentration of aluminum in atomic concentration in the Al-variable AlCrN layer, when only aluminum and chromium are considered for the calculation (see for example the schematically shown coating architecture in FIG. 1), wherein:
the Al-variable AlCrN layer is deposited as transition layer between the non-Al-rich AlCrN layer and the Al-rich AlCrN layer, and
x is in a range of 0.76<x≤0.82 (higher than 0.76 and lower than or equal to 0.82), and
the AlₓCr₁₋ₓN layer preferably exhibits a SEM morphology (layer morphology observed in scanning electron microscopy images) corresponding to an intermediate growth (i.e. not only columnar growth and not only fine-grained growth but a growth combining columnar and fine-grained growth-such kind of growth is for example shown in FIG. 2, see SEM image in the middle), and
the AlₓCr₁₋ₓN layer preferably exhibits crystalline structure exhibiting face centered cubic phase (fcc phase) that can be detected for example by XRD analysis (by analyzing diffractograms produced by using x-ray diffraction analytical techniques, and
y is in a range of 0.60≤y≤0.76 (higher than or equal to 0.60 and lower than or equal to 0.76), and
the Al_{y}Cr_{1-y}N layer preferably exhibits a SEM morphology (layer morphology observed in scanning electron microscopy images) corresponding to a columnar growth. i.e. does not comprising fine-grained growth-such kind of growth is for example shown in FIG. 2, see SEM image on the left side), and
the Al_{y}Cr_{1-y}N layer preferably exhibits crystalline structure exhibiting face centered cubic phase (fcc phase) that can be detected for example by XRD analysis (by analyzing diffractograms produced by using x-ray diffraction analytical techniques), and
z is in a range of 0.60≤y≤0.82, where z is preferably not constant but varies from a low value z₀ up to a high value z₁, wherein z₀≥y, and z₁≤x, and
the Al_{z}Cr_{1-z}N layer preferably exhibits a SEM morphology (layer morphology observed in scanning electron microscopy images) corresponding to a columnar growth or an intermediate growth), and
the Al_{z}Cr_{1-z}N layer preferably exhibits crystalline structure exhibiting face centered cubic phase (fcc phase) that can be detected for example by XRD analysis (by analyzing diffractograms produced by using x-ray diffraction analytical techniques).

According to a preferred embodiment of the present invention, the inventive coating is provided on a surface of a substrate, in such a manner that the non-Al-rich AlCrN layer is deposited closer to the substrate than the Al-rich AlCrN layer.

The non-Al-rich AlCrN layer can be deposited directly on the surface of the substrate (see FIG. 1.a).

It is however also possible to deposit an adhesion layer 10 between the non-Al-rich AlCrN layer and the substrate 1 (see FIG. 1.b).

The Al-rich AlCrN layer is preferably the top layer (outermost layer) of the coating.

According to a preferred embodiment of the present invention the thickness of the AlCrN layers is in following ranges:
The thickness of the Al-rich AlCrN layer is between 34% and 41% of the sum of the thicknesses of the Al-rich AlCrN layer, the thickness of the non-Al-rich AlCrN layer and the thickness of the Al-variable AlCrN layer.
The thickness of the non-Al-rich AlCrN layer is between 29% and 35% of the sum of the thicknesses of the Al-rich AlCrN layer, the thickness of the non-Al-rich AlCrN layer and the thickness of the Al-variable AlCrN layer.
The thickness of the Al-variable AlCrN layer is between 28% and 34% of the sum of the thicknesses of the Al-rich AlCrN layer, the thickness of the non-Al-rich AlCrN layer and the thickness of the Al-variable AlCrN layer.

Preferably the thickness of the Al-rich AlCrN layer is higher than the thickness of the non-Al-rich AlCrN layer, more preferably at least 1.5 times higher, still more preferably at least 2 times higher, for example between 1.5 and 3 times higher.

Preferably the thickness of the non-Al-rich AlCrN layer is equal to or higher than the thickness of the Al-variable AlCrN layer, more preferably at least 1.3 times higher, still more preferably at least 1.5 times higher, for example between 1 and 3 times higher.

According to a further preferred embodiment the coating consists of the Al-rich AlCrN layer, the Al-variable AlCrN layer, and the non-Al-rich AlCrN layer, wherein each one of these AlCrN layers can be deposited as monolayer or multilayer, respectively.

In the case of depositing one or more of the AlCrN layers as multilayer, the multilayer structure can be formed by nanolayers (layers having individual thickness in nanometer size, i.e. 100 nm or lower) differing in at least one property, for example differing in content of aluminum.

Another object of the invention is a substrate, coated with an AlCrN-based coating described above, wherein the non-Al-rich AlCrN layer is deposited closer to the substrate than the Al-rich AlCrN layer.

Hereby, it may be provided that the non-Al-rich AlCrN layer is deposited directly on the surface of the substrate.

It may also be provided that an adhesion layer is arranged between the non-Al-rich AlCrN layer and the substrate.

Moreover, it may be provided that the Al-rich AlCrN layer is the top layer of the coating.

Another object of the invention is a method for producing an AlCrN-based coating described above, preferably a substrate described above, wherein a PVD coating method is used for applying the Al-rich AlCrN layer, the non-Al-rich AlCrN layer and the Al-variable AlCrN layer.

Hereby, the PVD coating method may comprise an arc evaporation or a sputtering deposition or a pulsed Laser deposition.

It may be further provided that the coating conditions are varied for applying the Al-rich AlCrN layer and the non-Al-rich AlCrN layer and the Al-variable AlCrN layer.

In particular, with respect to the following parameters:
substrate temperature,
bias voltage,
target composition,
pressure of a reactive gas.

In this regard it is proposed in the present invention to focus:
the connection/relationship between process, structure, properties and performance in more detail (hereafter also called PSPP connection), and
the incorporation of a high aluminum content (abbreviated Al content)

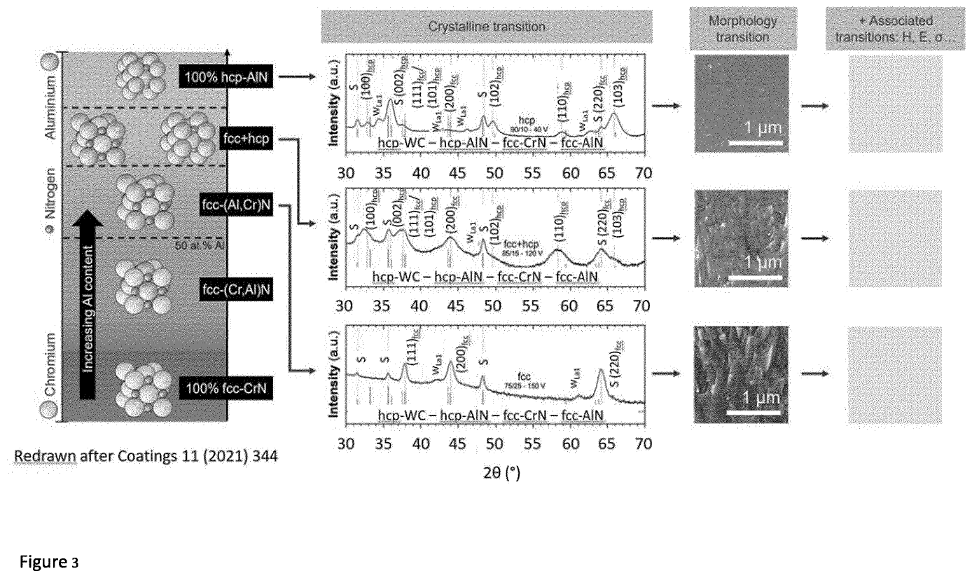

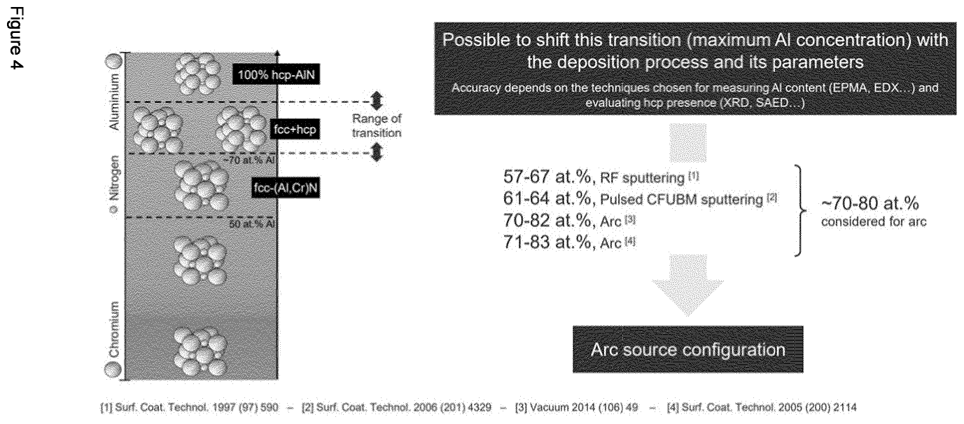

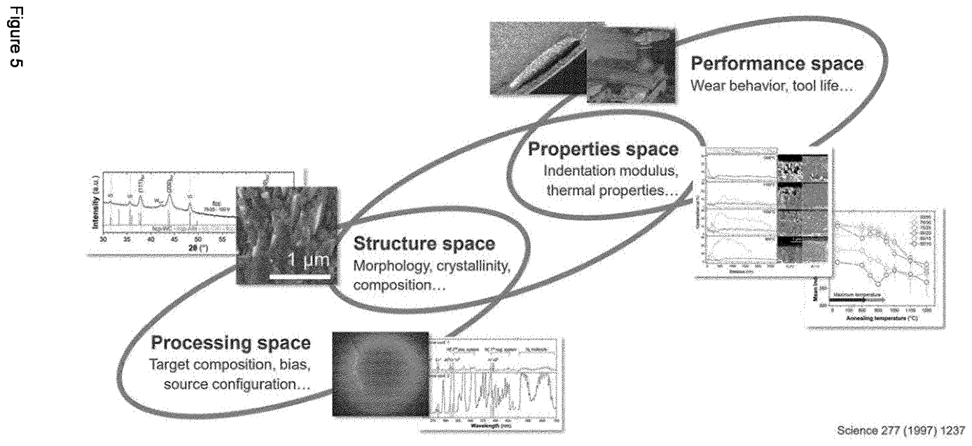

For understanding better the AlCrN system, the FIGS. 3 and 4 are used to show how the AlCrN system is mostly governed by its Al content.

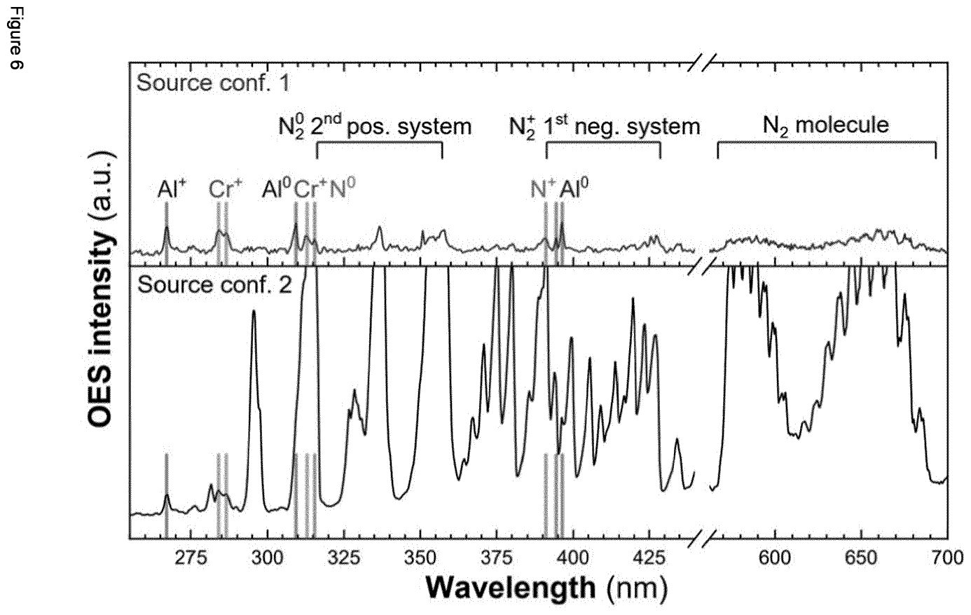

Further the FIG. 5 is used to show a three-link chain model for the materials science paradigm PSPP.

In the present description, the Al content in AlCrN will be considered without taking into account N, we shall then have the sum of the Al and Cr contents equal to 100 at. %. We will be particularly interested in the transition from fcc-(Al, Cr)N to fcc-(Al, Cr)N+hcp-AlN, that is usually spotted between 70 and 80 at. % for arc coatings. Below this transition for PVD coatings, for example for Al contents between 50 and 70 at. %, we have a fcc-(Al, Cr)N crystal structure that gives the coating a strong columnar morphology with usually relatively high indentation hardness HIT and indentation modulus EIT. For Al contents above this transition (>70 at. %), it is commonly agreed that the morphology becomes progressively fine-grained and HIT and EIT drop to lower values (see FIG. 3 showing the influence of the Al content on the properties of AlCrN deposited by PVD techniques, including corresponding crystal structure and morphology, and FIG. 4 showing the transition from fcc-(Al, Cr)N to fcc-(Al, Cr)N+hcp-AlN, example of Al content values obtained with different PVD processes).

For intensive cutting and forming applications, the fcc-(Al, Cr)N phase is preferred. Maintaining the fcc-(Al, Cr)N phase with higher Al contents is believed to be beneficial for many cutting and forming applications but is not an easy task. However this invention provide a method for producing Al-rich AlCrN layers with the fcc-(Al, Cr)N phase and the incorporation of these layers into a coating for cutting and forming tools exhibiting improved performance.

For the present invention, two different types of Oerlikon Balzers arc sources, which allow generating different plasma conditions were used. This is possible because of the different source design (arc steering rate, adjusted magnetic field lines and electrical configuration, arc burning voltage . . . ). It was possible to make correlations between the arc source design, plasma conditions and the coating properties.

In this manner the inventors determined that the first source having a first configuration (hereafter also called as source configuration 1) helped to attain a reduced ionization of the reactive gas, while the second source having a second configuration (hereafter also called as source configuration 2), allowed a higher ionization of the reactive gas than the first source configuration (in case of using the AlCrN system, as for example in this case, a higher ionization of the nitrogen reactive gas).

In FIG. 6 OES measurements (OES measurements) concerning ionization of reactive gas by using the two source configurations are shown.

The measurements were carried out by arcing AlCr 70/30 targets in pure N2. Following observations could be made from looking at the plasma in the deposition chamber, and from looking at the OES measurements:
Source configuration 1:
   Smaller plasma expansion into the chamber, lower optical intensity
   Colder electron temperature
Source configuration 2:
   Larger plasma expansion into the chamber, higher optical intensity (here enough to saturate the detector)
   Hotter electron temperature
   Extensive additional nitrogen ionization (→higher nitrogen ionization)

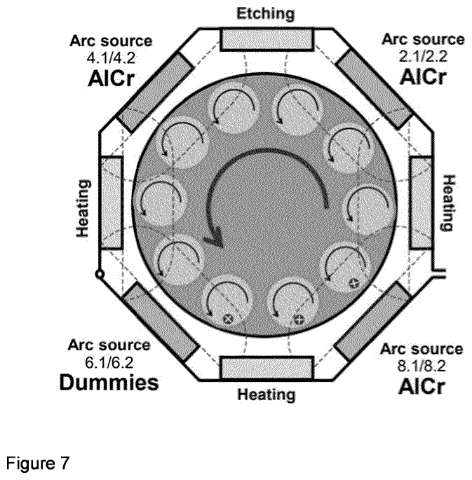

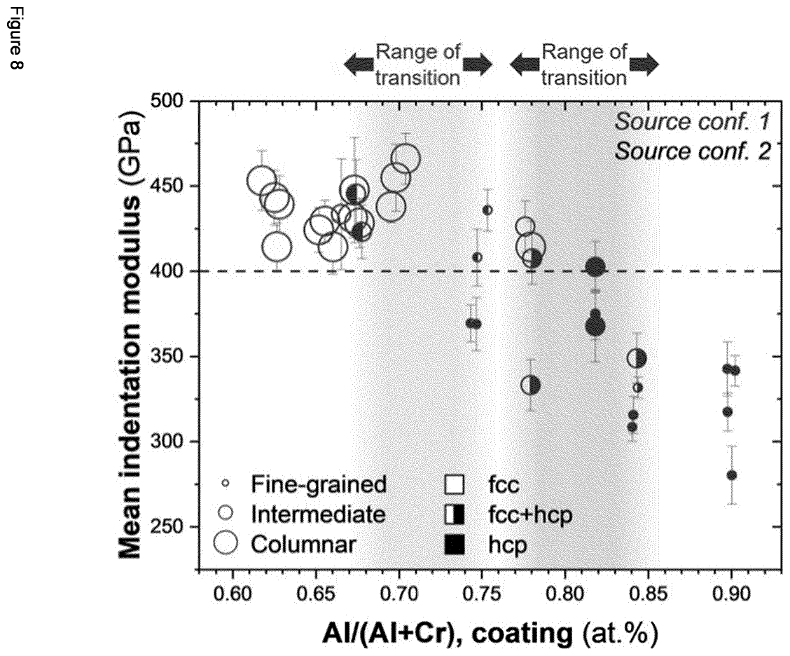

In this manner it was possible to generate two very distinct plasma configurations with AlCr (i.e. AlCrN). In the following study, several coatings with various Al contents could be deposited and characterized. Here are the experimental details:
Arc process used:
   Carried out at a coating plant of the type INNOVENTA kila, industrial scale coater,
   Partial nitrogen pressure (P_{N2}) was maintained at about 4 Pa (P_{N2}=4 Pa),
   Six sources on three flanges (see FIG. 7);
   Source conf. 1 and 2;
   Negative bias voltage range from −40 V to −150 V, in particular Ubias=−40 V, −80 V, −120 V and −150 V,
Materials:
   Alloyed AlCr targets as coating source materials, in particular having ratio Al/Cr of chemical element composition in atomic percentage in a range between 50/50 and 90/10, in particular Al/Cr=50/50, 70/30, 75/25, 80/20, 85/15 and 90/10,
   WC: Co and steel as substrate materials,
Characterizations and testing of properties, in particular coating properties:
   Morphology, chemical element composition, measured/determined in particular by using known SEM and EDX techniques/methods,
   Crystal structure, determined in particular by using known XRD, T2T and GI (grazing incidence) techniques/methods,
Indentation hardness and modulus, measured/determined in particular by using known nanoindentation techniques/methods-indirect evaluation of hcp,
Thermal stability, evaluated in particular by using a vacuum annealing process (in particular, 30 min at a setpoint temperature Tₛₑₜ)

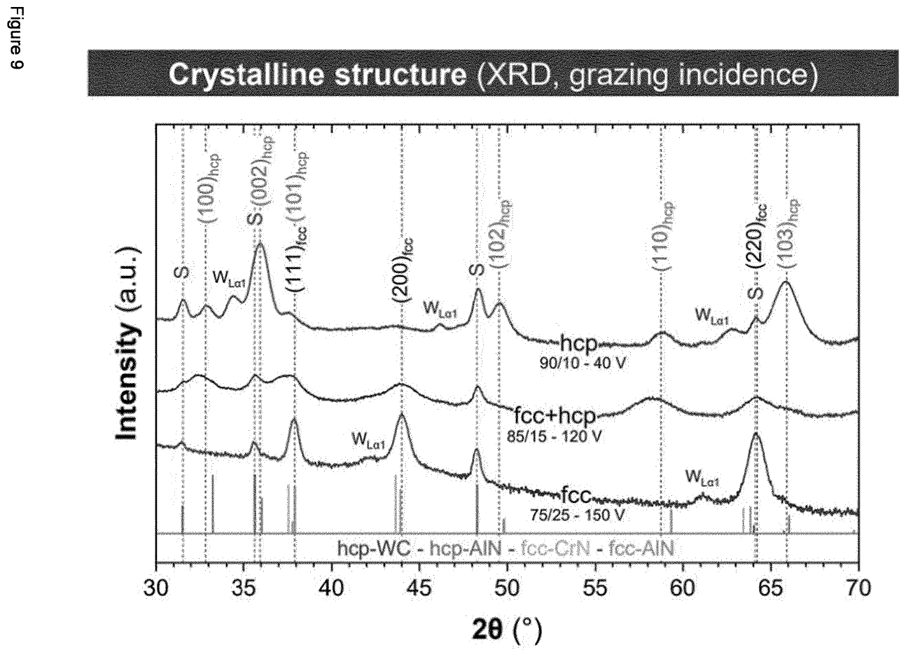

The AlCrN system reactivity with Al content and source configuration is shown in FIGS. 8, regarding the evolution of the indentation modulus EIT, morphology and crystal phase. The crystal phases are shown with “fcc” for fcc-(Al, Cr)N and “hcp” for hcp-AlN We can clearly see the transitions in the crystal structure, morphology and EIT. With a growing Al content, we go from a columnar fcc coating having EIT>400 GPa to a fine-grained hcp coating having EIT<400 GPa.

The attribution of discrete values for several coating characteristics was done to help data analysis. FIGS. 2 (showing attribution of discrete values for several coating characteristics to help data analysis, here with the morphology: columnar, intermediate and fine-grained) and 9 (showing attribution of discrete values for several coating characteristics to help data analysis, here with the crystalline structure: fcc, fcc+hcp and hcp) present this attribution respectfully for the coating morphology and crystal structure.

The fcc to hcp transition could be shifted thanks to the source configuration for the following Al contents:
67-75 at. % Al for conf. 1, with a turning point between AlCr 75/25 and 80/20 tar-gets,
78-84 at. % Al for conf. 2, with turning point between AlCr 80/20 and 85/15 targets.

Thus, it was attained:
Beneficial effect of source conf. 2, in this case by attaining an additional nitrogen (N) ionization,
It was possible to deposit fcc-(Al, Cr)N with 78 at. % Al still having EIT>400 GPa, using AlCr 80/20 targets.

Interestingly, our source configuration and the particular high nitrogen ionization, made it possible to achieve a cubic coating with a higher Al content than what is reported in the literature for arc coatings.

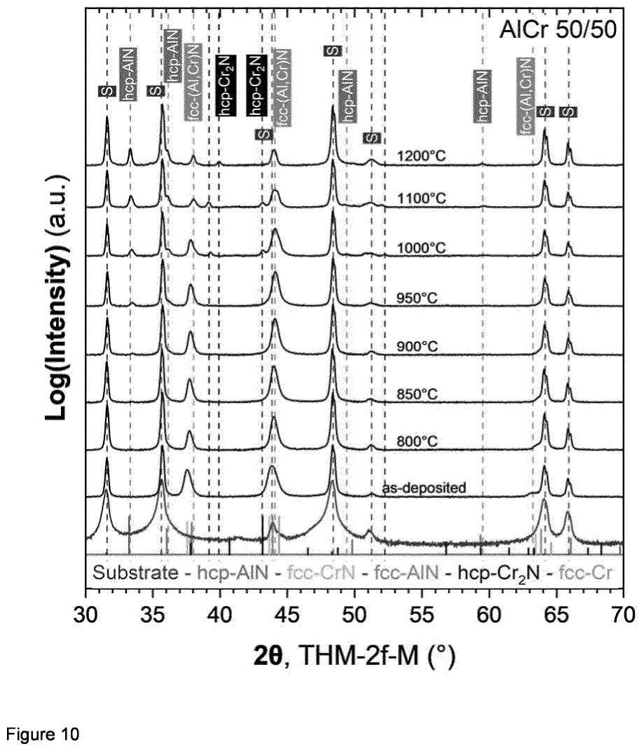

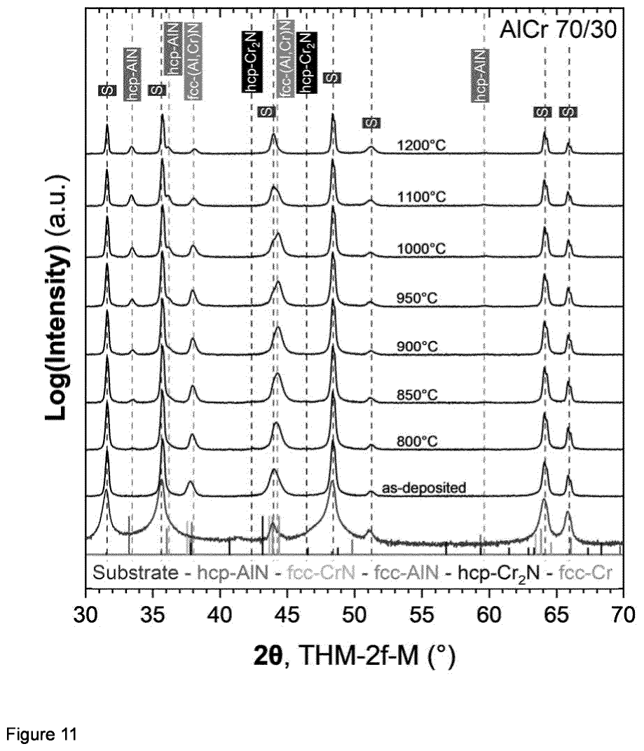

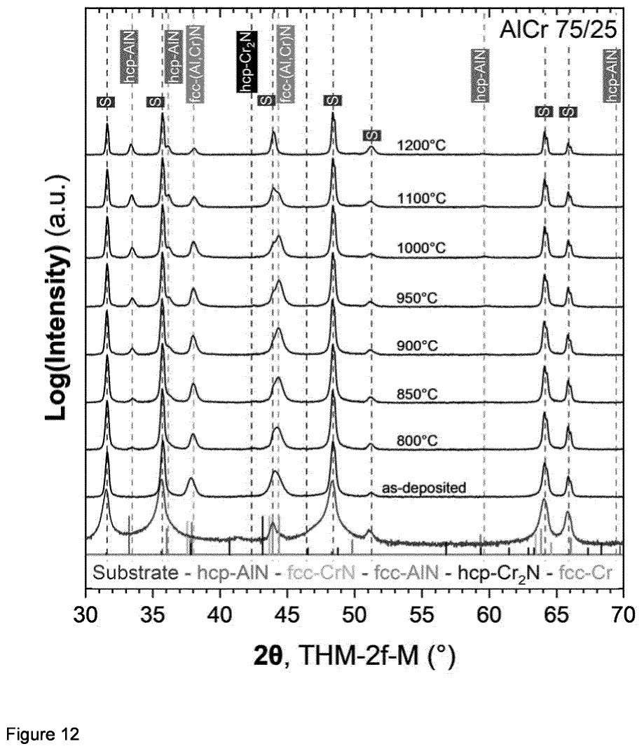

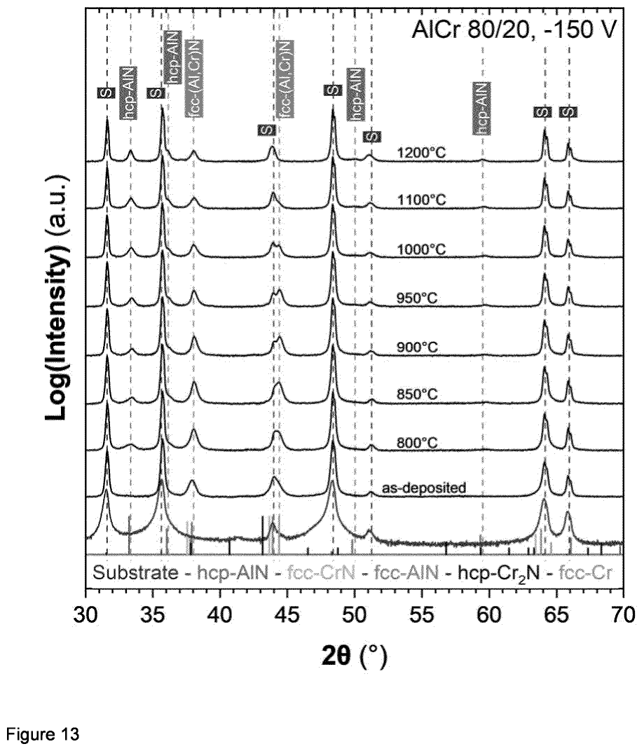

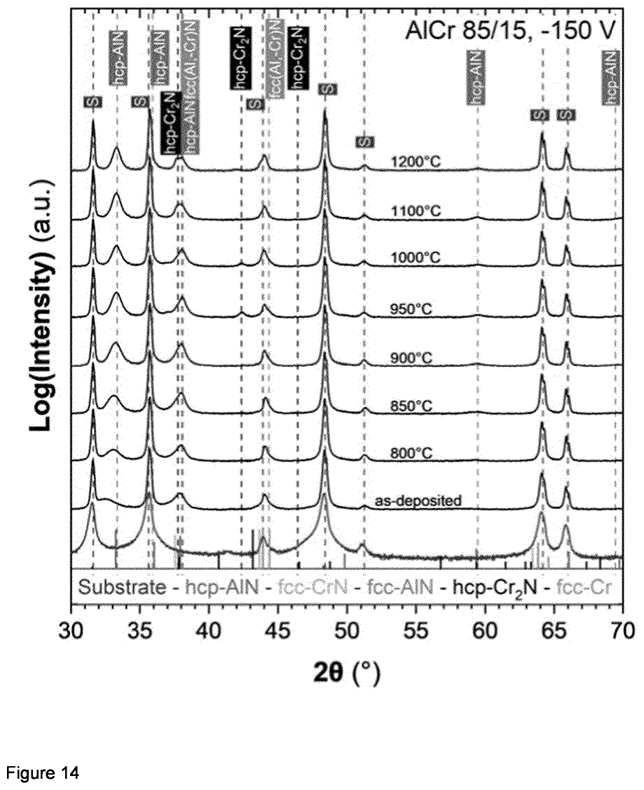

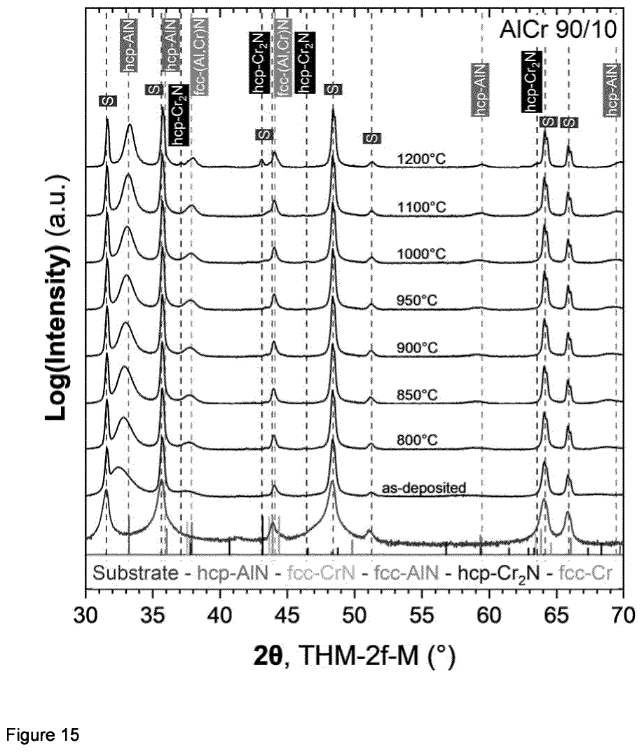

The behavior at high temperatures of AlCrN with an increasing Al content was also analyzed. Thermal stability experiments were conducted by annealing of the coatings in vacuum. The results concerning annealing are reported here concerning the coatings deposited with source conf. 2 and at a high bias (−150 V). The XRD evolution of AlCrN coatings de-posited on WC: Co substrates with AlCr 50/50, 70/30, 75/25, 80/20, 85/15 and 90/10 targets during vacuum annealing are shown in FIGS. 10 to 15 (XRD patterns of an AlCrN coating deposited with targets AlCr 50/50, 70/30, 75/25, 80/20, 85/15, and 90/10, after 30 minutes annealing under vacuum at various temperatures). The evolution of the AlCrN system with an increasing of the temperature is the following:
hcp-AlN (or hcp-(Al, Cr)N) crystallizes;
fcc-(Al, Cr)N crystallizes and then disappears around 1100° C.;
hcp-Cr₂N is identified around 950° C.

These phenomena occur at a different rhythm, according to the composition of the as-deposited coating. For example, a coating deposited with AlCr 50/50 targets, which does not have any hcp-AlN in his as-deposited state, will start showing the first signs of hcp-AlN at 900° C. On the other hand, a coating deposited with AlCr 90/10 targets is already showing a significant amount of hcp-AlN in his as-deposited state even before being an-nealed. Some remarks need to be considered regarding the above-mentioned results:
There was no trace of metallic Cr or phases resulting from interdiffusion with the substrate (WC: Co);
The WC: Co substrate is not ideal for XRD identification (choice was made regard-ing the tooling application);
It is difficult to identify precisely the peak around 38° because of the superposition of all phases.

It was possible to map the phase transformations with the temperature (T). Global trends were similar to the literature, with T and Al content values to adjust, nuanced by the bias.

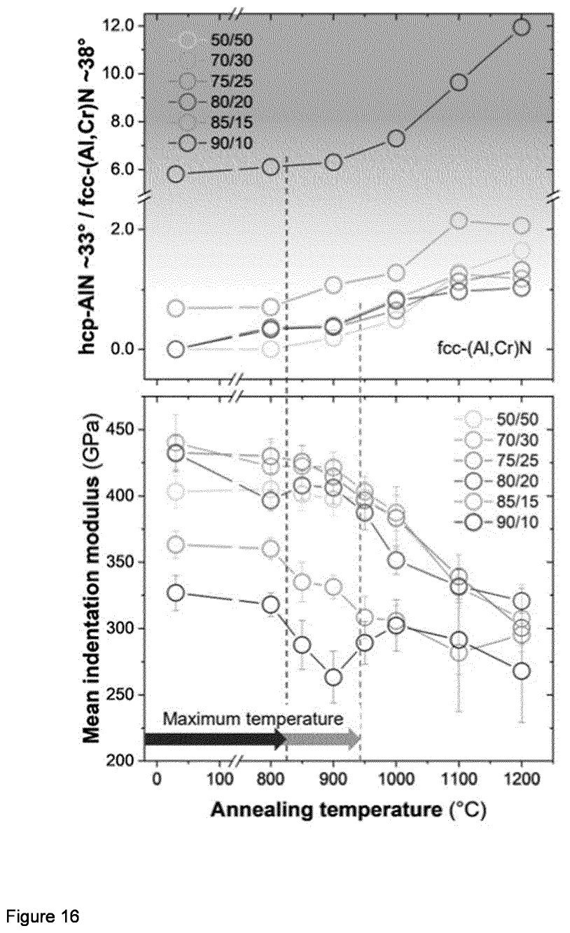

Further results regarding AlCrN system evolution with vacuum annealing are shown in FIG. 16 (Evoution with the annealing temperature of the mean indentation modulus and of the XRD intensity ratio of the peak around 33° (connected to hcp-AlN) over the peak around 38° (connected to fcc-(Al, Cr)N), for AlCrN coatings deposited with AlCr 50/50, 70/30, 75/25, 80/20, 85/15 and 90/10 targets), with the evolution of the indentation modulus EIT and of the XRD intensity ratio of the peak around 33° (connected to hcp-AlN) over the peak around 38° (connected to fcc-(Al, Cr)N). We can identify two groups of coatings according to the situation com-pared to the Al content threshold triggering the fcc to hcp transition:
First group, below the threshold (50/50 to 80/20) with EIT>400 GPa for as-deposited coatings
Second group, above threshold (85/15 and 90/10) with EIT<400 GPa for as-deposited coatings

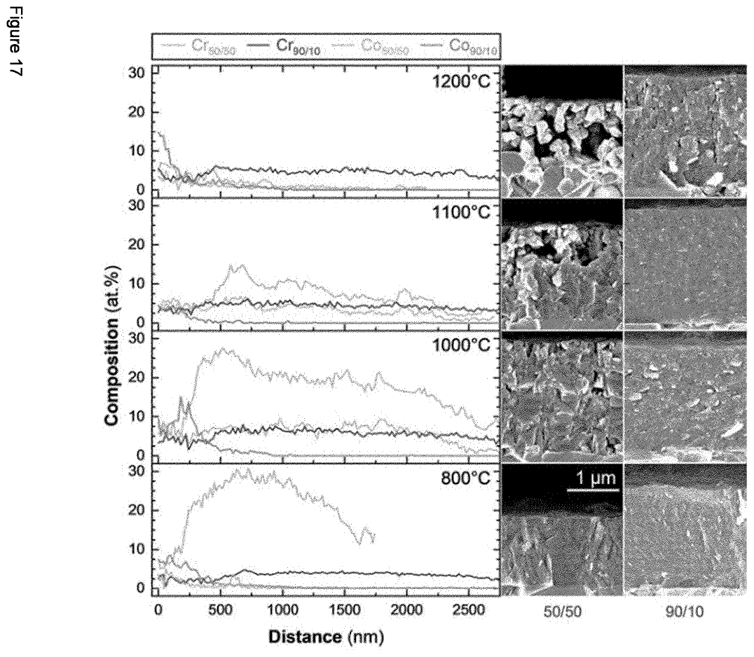

In addition, we can observe a “maximum” temperature before the mechanical properties drop. This maximum temperature is higher for the first group of coatings (AlCr 50/50 to 80/20) with around 940° C. vs 825° C. for the second group (AlCr 85/15 and 90/10). The lower mechanical properties at high temperatures are related to the morphology changes, in addition to the structural changes (see the SEM cross-sections in FIG. 17: SEM cross-sections, Co and Cr EDX profiles of vacuum annealed AlCrN coatings deposited with AlCr 50/50 and 90/10 targets). FIG. 17 shows the evolution of two AlCrN coatings, deposited with AlCr 50/50 and 90/10 targets, after vacuum annealing. We can say the following with the increasing temperature:
Cr content is decreasing
Co content is increasing and then decreasing
Morphology gets finer, porosities appear from top

The inventors propose following mechanism, based on the present results:
Cr is diffusing outwards, leaving porosities while Co diffuses simultaneously from the substrate to the outer surface
For the highest Al/Cr ratios, there is less initial Cr, less Cr and Co diffusion, less morphology changes and less porosities at the end

It can be concluded that the high Al-containing AlCrN layers, which maintain a fcc-(Al, Cr)N in their as-deposited state are of particular interest regarding diffusion processes and stability at high temperatures (here in vacuum). In our case, we are talking about the coatings from the first group that contain the most Al, meaning layers deposited with AlCr 80/20 targets, which are the most promising.

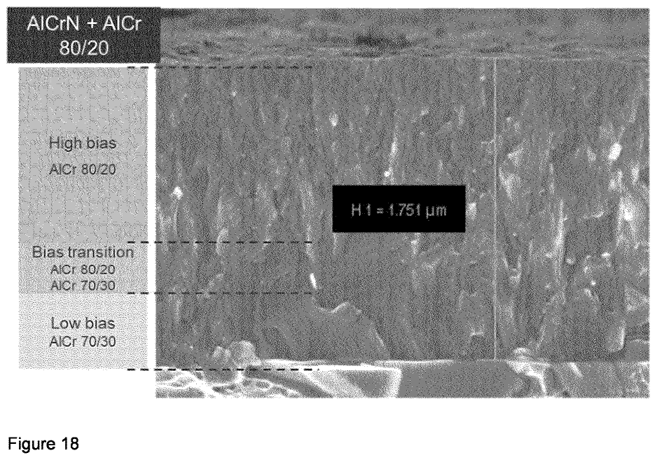

In the present invention, the inventors found that the coating denominated “AlCrN+AlCr 80/20”, having one top layer deposited with AlCr 80/20 targets (this top layer also called in the present invention Al-rich AlCrN layer 40). This layer deposited using source conf. 2 is constituted of fcc-(AlCr)N with 78 at. % of Al, while maintaining an indentation modulus above 400 GPa. Taking advantage of this layer, our newly proposed coating is made from three layers: (i) a bottom layer, (ii) a transition layer and (iii) a top layer. In order to limit the complexity of the coating and of its production, the coating was designed without adhesion layer. The bottom layer consists only of arcing AlCr 70/30 targets at low bias. The top layer consists of arcing only AlCr 80/20 targets at high bias. The transition layer consists of arcing both AlCr 70/30 and AlCr 80/20 targets with a bias transition, from low to high. All the three layers are deposited in a nitrogen pressure-controlled atmosphere. The morphology and design of this inventive coating is provided in the SEM cross-section image shown in FIG. 18 (SEM cross-section of the coating AlCrN+AlCr 80/20).

The transition layer (also called Al-variable AlCrN layer 30 or transition layer) that is joining the bottom layer (also called non-Al-rich AlCrN layer 20) and the top layer (also called Al-rich AlCrN layer 40) is an important element. It is supposed to give space for the morphological transition to occur, from strong columnar to less strong columnar. As this transition is also accompanied by a stress transition, this interface could be a weaker spot in the coating. We increased the thickness of the transition layer to strengthen the connection between the bottom and top layers. The transition layer is now around 500 nm for a total coating thickness of 3 μm, whereas we usually design thinner transition layer, around 50-100 nm.

The coating combines several features giving a clear advantage in a large diversity of cut-ting and forming operations when applied on a tool. The technical challenge is to in-crease the performance of already existing coatings, which are already at a very good level. An effort was provided on several fronts, to give the coating a combination of ad-vantages through particular features, especially regarding the limits mentioned in the previous paragraph.

As mentioned before, using an AlCrN top layer with 78 at. % of Al has several impacts that we described in our study presented above, that we can use at our advantage:
Refining the morphology of the coating from a strong columnar growth to a light columnar growth,
Maintaining or increasing the indentation hardness,
Decreasing the indentation modulus,
Increasing the stability of the morphology of the AlCrN coating at high temperatures,
Decreasing the sensibility to diffusion processes at high temperatures,
Potentially decrease the thermal conductivity with the increased Al content.

These features give several advantages to the coating.

Firstly, the coating is provided a combination of several morphologies, with a strong columnar bottom layer, and a less strong columnar top layer and a transition layer in-between to accommodate this change. The less strong columnar layer offers the advantage to stay better at the cutting edge of a cutting too, while the strong columnar bot-tom layer gives a strong base for the coating to grow. In addition, in order to propose a broad-band coating, we believe that combining two different morphologies is advantageous and is a good compromise, strong columnar morphology helping in applications where strong columnar morphology is better suited and less strong columnar morphology helping in applications where less strong columnar morphology is better suited. It was also shown that a coating exhibiting this combination of two morphologies (strong and less strong columnar growth), performs better than a coating exhibiting only strong columnar growth, or a coating exhibiting only a less strong columnar growth.

In order to counter the appearance of thermal stresses and associated cracks opening and propagation, that can be for example the case in an interrupted cutting operation ran in wet conditions, the coating has a relatively high level of compressive stresses, combined with the multiplication of internal interfaces.

Thirdly, as a consequence of increasing or maintaining H and reducing E, the H/E ratio is increasing. As the H/E ratio is widely recognized as a criterion to maximize in order to ensure a better resistance to crack propagation and a better wear resistance, it is another advantage in the present invention.

Finally, one last advantage from incorporating a higher content of Al in AlCrN is that it provides a better behavior at high temperatures. The morphology is stable at higher temperatures, and the diffusion processes are slowed down. This is very important to ensure that the mechanical properties and the integrity of the coatings are maintained as much as possible, which is crucial for cutting or forming operations where high temperatures are reached.

Combining all these advantages gave us increased performance in several cutting and forming operations (yet wet finishing with carbide endmills, dry face milling with HSS inserts and several different gear cutting tests).

### Example of the Present Invention Used for Showing Cutting Tests Results

As described above the inventive coating AlCrN+AlCr 80/20 is made from three layers: (i) an AlCrN bottom layer deposited from AlCr 70/30 tar-gets at low bias, (ii) an AlCrN transition layer deposited from AlCr 70/30 and AlCr 80/20 targets and (iii) an Al-rich AlCrN top layer deposited from AlCr 80/20 targets at high bias. These three layers are deposited using a nitrogen pressure-controlled atmosphere (typically 3.5-4 Pa). In this example (which should not be as a limitation of the present invention but just as a showcase of the present invention), the negative bias voltage applied on the carousel holding the substrates was a bias voltage value between −10 and −60 V for the bottom layer, for the transition layer a bias voltage value was used that at the beginning was the same used at the end of the bottom layer and an the end was the same used at the beginning of the top layer and for the top layer a bias volage between −90 and −150 V was used. In this example the thickness of the layers for a total coating thickness of 3 μm:
Bottom layer: 0.75 μm
Transition layer: 0.5 μm
Top layer: 1.75 μm

In many examples of this same type of inventive coating the bias voltage value used for the deposition of the bottom layer was maintained constant e.g. about −40 V and also for the deposition of the top layer, e.g. about −120 V, while the bias voltage value was only varied (increased) during the deposition of the transition layer. These coating examples obtained also comparable very good results in all cutting tests.

The properties of each AlCrN layer of the coating example described above are listed in Table 1. The properties of the coatings investigated in cutting tests are given in Table 2.

### Cutting Test 1 (Cutting Laboratory):

The coating AlCrN+AlCr 80/20 was tested in a wet finishing operation with 10 mm squared endmills. It was compared to two others coatings:
“AlCrN+AlCr 75/25”, which is similar to AlCrN+AlCr 80/20 deposited with the use of AlCr 75/25 targets instead of AlCr 80/20 ones
“AlCrN+AlCr 70/30”, which is similar to AlCrN+AlCr 80/20 deposited with AlCr 70/30 targets instead of AlCr 80/20 ones, with a transition layer being 75 nm thick and having a maximum bias voltage of 150 V, and with a 150 V bias voltage ap-plied during the deposition of the top layer
   Cutting Parameters were as Following:
Workpiece: 1.2344, 45 HRC
Tool: 10 mm carbide endmill (2 tools per coating variant)
Vc=220 m/min
fz=0.10 mm
ap=10.00 mm
ae=0.50 mm
Test criteria: Maximal admissible flank wear of 100 μm

The modifications of the coating properties, thanks to the use of the Al-rich AlCrN layer and the thicker transition layer led to an enhanced tool life, with +22% and +29% respect-fully for AlCrN+AlCr 75/25 and for AlCrN+AlCr 80/20, compared to the reference coat-ing AlCrN+AlCr 70/30. In this interrupted cutting operation with coolant, the coating fac-es strong thermal shocks, in addition to all the other constraints.

### Cutting Test 2 (Cutting Laboratory):

AlCrN+AlCr 80/20 was further investigated in another cutting test: dry face milling with round HSS inserts. This test was developed as a gear cutting analogy test, being an inter-rupted cutting operation with a variable undeformed chip thickness. The cutting parame-ters were optimized for the crater wear to be the predominant wear mechanism when us-ing HSS tools. Thermal softening of the tool material is responsible for the crater for-mation, if the heat generated by the cutting operation does not flow enough into the chips and goes instead in the tool. Thermal softening can be avoided with adequate thermal management, by using for example a coating with a low heat conductivity, that could be provided by Al-rich AlCrN layers. AlCrN+AlCr 80/20 was compared to two other coatings:
“AlCrN+AlCr 70/30”, which is similar to AlCrN+AlCr 80/20 deposited with AlCr 70/30 targets instead of AlCr 80/20 ones, with a transition layer being 75 nm thick and having a maximum bias voltage of 150 V, and with a 150 V bias voltage ap-plied during the deposition of the top layer
“AlCrN+AlCr 50/50, which is similar to AlCrN+AlCr 80/20 deposited with AlCr 50/50 targets instead of AlCr 80/20 ones, with a transition layer being 75 nm thick and having a maximum bias voltage of 150 V, and with a 150 V bias voltage applied during the deposition of the top layer

### Cutting Parameters are as Followed:

Workpiece: 1.7225, 42CrMo4
Tool: 12 mm diameter round HSS inserts (1 tool per coating variant)
Vc=120 m/min
fz=0.40 mm
ap=2.00 mm
ae=20.00 mm
Test main observation: Crater wear development

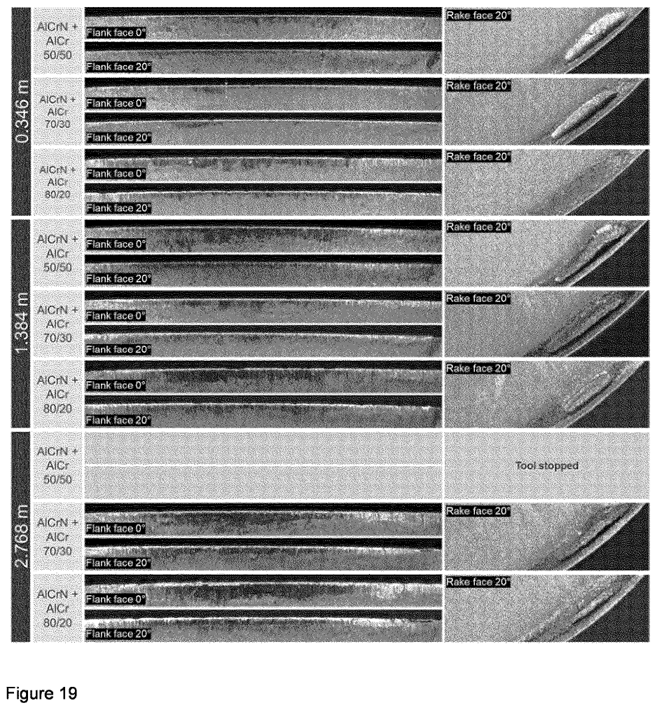

Results are presented in FIG. 19 (FIG. 17: Observations of the flank and rake faces of HSS inserts coated with AlCrN+AlCr 50/50, AlCrN+AlCr 70/30 and AlCrN+AlCr 80/20 at different cutting lengths (in m) during dry face milling of 1.7225), with the observations of the worn areas (flank wear at 0° and 20° and rake face at) 20°. The modification of the coating properties due to the in-creased Al content in the AlCrN top layer grants an enhanced resistance to crater wear. At the initial wear (0.346 m, there is no crater at all for AlCrN+AlCr 80/20, while larger ones already developed on the rake face of the tools coated with AlCrN+AlCr 50/50 and with AlCrN+AlCr 70/30. For longer cutting lengths (1.384 and 2.768 m), a crater is visible for all three coatings, but is systematically smaller for AlCrN+AlCr 80/20. Moreover, the craters for AlCrN+AlCr 50/50 are systematically the largest ones.

In addition to these two previous cutting tests performed in a cutting laboratory, some gear cutting tests could be done in production conditions at various automotive or powertrain manufacturers. We present here a selection of gear cutting tests done at major European manufacturers.
Carbide stick blades at a European automotive manufacturer: AlCrN+AlCr 80/20 reaches+30% tool life compared to AlCrN+AlCr 70/30. Dry cutting of 20MnCrS5 at Vc around 200 m/min.
HSS hobs (module around 2.5) at a European automotive manufacturer: AlCrN+AlCr 80/20 reaches+45% tool life compared to AlCrN+AlCr 70/30. Dry cutting of 20MnCrS5 at Vc around 250 m/min.
Carbide hobs (module around 2.2) at a European powertrain manufacturer: AlCrN+AlCr 80/20 reaches+100% tool life and shows less flank wear compared to AlCrN+AlCr 70/30. Dry cutting of 20MnCrS5 at Vc around 350 m/min.
Carbide hobs (module around 2.6) at a European powertrain manufacturer: AlCrN+AlCr 80/20 reaches+180% tool life and shows similar flank wear compared to AlCrN+AlCr 70/30. Dry cutting of 20MnCrS5 at Vc around 350 m/min.
HSS hobs (module around 3.5) at a European powertrain manufacturer: AlCrN+AlCr 80/20 reaches+50% tool life and shows less flank wear compared to AlCrN+AlCr 70/30. Wet cutting of 17CrNi6-6 at Vc around 100 m/min.

TABLE 1

| | | | Transition layer | | |
|---|---|---|---|---|---|
| | | | (batches 1233 to 1234) | | |
| | | | Close to | Close to | |
| | Total coating | Bottom layer | botom layer | top layer | Top layer |
| Property | (batch 1310) | (batch 1202) | (batch 1233) | (btach 1234) | (batch 1287) |
| Morphology | Mixed | Strong | Intermediate | Intermediate | Less |
| | | columnar | | | columnar |
| Crystal | fcc (111) | fcc (111) | fcc (111) + | fcc (200) | fcc (200) |
| structure | I₍₁₁₁₎/ | I₍₁₁₁₎/ | minor | I₍₁₁₁₎/ | I₍₁₁₁₎/ |
| and | I₍₂₀₀₎ = 1.307 | I₍₂₀₀₎ = 1.803 | hcp (002) | I₍₂₀₀₎ = 0.956 | I₍₂₀₀₎ = 0.996 |
| (111)/(200) | | | I₍₁₁₁₎/ | | |
| XRD | | | I₍₂₀₀₎ = 1.113 | | |
| intensity | | | | | |
| ratio | | | | | |
| Crystallite | 202 | 304 | 201 | 208 | 204 |
| size (111)_{fcc} | | | | | |
| (Å) | | | | | |
| Crystallite | 254 | 249 | 129 | 162 | 216 |
| size | | | | | |
| fcc(200)_{fcc} | | | | | |
| (Å) | | | | | |
| Al/Cr EDX | 77.9/22.1 | 67.6/32.4 | 73.4/26.6 | 71.7/28.3 | 78.2/21.8 |
| ratio | | | | | |
| (at. %) | | | | | |
| Indentation | 42.5 ± 2 | 38.1 ± 1.7 | 37.3 ± 2 | 38.1 ± 1.5 | 41.4 ± 1.5 |
| hardness | | | | | |
| HIT (GPa) | | | | | |
| Indentation | 410 ± 13 | 428 ± 15 | 359 ± 15 | 413 ± 14 | 415 ± 10 |
| modulus | | | | | |
| EIT (GPa) | | | | | |
| Bending | −3.8 | −3.1 | −2.3 | −4.2 | −4.6 |
| stresses | | | | | |
| (GPa) | | | | | |

Table 1: Properties of the proposed coating AlCrN+AlCr 80/20 and of its individual layers

TABLE 2

| | AlCrN + | AlCrN + | AlCrN + | AlCrN + |
|---|---|---|---|---|
| | AlCr | AlCr | AlCr | AlCr |
| | 50/50 | 70/30 | 75/25 | 80/20 |
| | (batch | (batch | (batch | (batch |
| | 1326) | 3786) | 1198) | 1310) |
| Indentation | 35.8 ± 2.1 | 42.3 ± 1.7 | 38.7 ± 1.8 | 42.5 ± 1.8 |
| hardness HIT | | | | |
| (GPa) | | | | |
| Indentation | 403 ± 14 | 422 ± 13 | 420 ± 19 | 410 ± 13 |
| modulus EIT | | | | |
| (GPa) | | | | |
| HIT/EIT ratio | 0.089 | 0.100 | 0.092 | 0.104 |
| Bending stresses | −3.1 ± 0.5 | −4.5 ± 0.5 | −4.6 ± 0.5 | −3.8 ± 0.5 |
| (GPa) | | | | |
| Al/Cr EDX ratio | 46/54 | 65/35 | 71/29 | 78/22 |
| (at. %) | | | | |

Table 2: Properties of the coatings investigated in the cutting tests

1.-24. (canceled)

25. An AlCrN-based coating, comprising:
an Al-rich AlCrN layer having a chemical element composition AlₓCr₁₋ₓN, x being a coefficient corresponding to atomic aluminum concentration in the Al-rich AlCrN layer, when only aluminum and chromium are considered for calculation,
a non-Al-rich AlCrN layer having a chemical element composition Al_{y}Cr_{1-y}N, y being a coefficient corresponding to atomic aluminum concentration in the non-Al-rich AlCrN layer, when only aluminum and chromium are considered for calculation, and
an Al-variable AlCrN layer having a chemical element composition Al_{z}Cr_{1-z}N, z being a coefficient corresponding to atomic aluminum concentration in the Al-variable AlCrN layer, when only aluminum and chromium are considered for calculation,
wherein the Al-variable AlCrN layer is a transition layer between the non-Al-rich AlCrN layer and the Al-rich AlCrN layer, and x is in a range of 0.76<x≤0.82, y is in a range of 0.60≤y≤0.76, and z is in a range of 0.60≤y≤0.82.

26. The AlCrN-based coating according to claim 25,
wherein the Al-rich AlCrN layer exhibits a SEM morphology corresponding to an intermediate growth.

27. The AlCrN-based coating according to claim 25,
wherein the Al-rich AlCrN layer has a crystalline structure exhibiting a face centered cubic phase detectable by XRD analysis.

28. The AlCrN-based coating according to claim 25,
wherein the non-Al-rich AlCrN layer exhibits a SEM morphology corresponding to a columnar growth.

29. The AlCrN-based coating according to claim 25,
wherein the non-Al-rich AlCrN layer has a crystalline structure exhibiting a face centered cubic phase detectable by XRD analysis.

30. The AlCrN-based coating according to claim 25,
wherein z is variable from a low value z₀ up to a high value z₁, wherein z₀≥y, and z₁≤x.

31. The AlCrN-based coating according to claim 25,
wherein the Al-variable AlCrN layer exhibits a SEM morphology corresponding to a columnar growth or an intermediate growth.

32. The AlCrN-based coating according to claim 25,
wherein the Al-variable AlCrN layer has a crystalline structure exhibiting a face centered cubic phase detectable by XRD analysis.

33. The AlCrN-based coating according to claim 25,
wherein a thickness of the Al-rich AlCrN layer is between 34% and 41% of a sum of the thickness of the Al-rich AlCrN layer, a thickness of the non-Al-rich AlCrN layer and a thickness of the Al-variable AlCrN layer.

34. The AlCrN-based coating according to claim 25,
wherein a thickness of the non-Al-rich AlCrN layer is between 29% and 35% of a sum of a thickness of the Al-rich AlCrN layer, the thickness of the non-Al-rich AlCrN layer and a thickness of the Al-variable AlCrN layer.

35. The AlCrN-based coating according to claim 25,
wherein a thickness of the Al-variable AlCrN layer is between 28% and 34% of a sum of a thickness of the Al-rich AlCrN layer, a thickness of the non-Al-rich AlCrN layer and the thickness of the Al-variable AlCrN layer.

36. The AlCrN-based coating according to claim 25,
wherein a thickness of the Al-rich AlCrN layer is higher than a thickness of the non-Al-rich AlCrN layer.

37. The AlCrN-based coating according to claim 25,
wherein a thickness of the non-Al-rich AlCrN layer is equal to or higher than a thickness of the Al-variable AlCrN layer.

38. The AlCrN-based coating according to claim 25,
wherein the AlCrN-based coating consists of the Al-rich AlCrN layer, the Al-variable AlCrN layer, and the non-Al-rich AlCrN layer.

39. The AlCrN-based coating according to claim 25,
wherein at least one of the Al-rich AlCrN layer, Al-variable AlCrN layer, and non-Al-rich AlCrN layer comprises nanolayers.

40. A coated component comprising:
a substrate coated with the AlCrN-based coating according to claim 25, wherein the non-Al-rich AlCrN layer is closer to the substrate than the Al-rich AlCrN layer.

41. The coated component according to claim 40,
wherein the non-Al-rich AlCrN layer is located directly on a surface of the substrate.

42. The coated component according to claim 40, further comprising:
an adhesion layer between the non-Al-rich AlCrN layer and the substrate.

43. The coated component according to claim 40,
wherein the Al-rich AlCrN layer is a top layer of the AlCrN-based coating.

44. A method for producing the AlCrN-based coating according to claim 25, comprising:
applying the Al-rich AlCrN layer, the non-Al-rich AlCrN layer, and the Al-variable AlCrN layer with a physical vapor deposition (PVD) coating method.
